(19) United States
(12) Patent Application Publication
(10) Pub. No.: US 2026/0006994 A1
(43) Pub. Date: Jan. 1, 2026

(54) DISPLAY PANEL AND DISPLAY DEVICE

(71) Applicant: Xiamen Tianma Display Technology Co., Ltd., Xiamen (CN)

(72) Inventor: Yongxiang LIN, Xiamen (CN)

(73) Assignee: Xiamen Tianma Display Technology Co., Ltd., Xiamen (CN)

(21) Appl. No.: 18/951,711

(22) Filed: Nov. 19, 2024

(30) Foreign Application Priority Data
Jun. 28, 2024 (CN) 202410867070.0

(51) Int. Cl. H10K 59/122; H10K 59/80

(52) U.S. Cl. CPC H10K 59/122; H10K 59/873

(57) ABSTRACT

The present application discloses a display panel and a display device. The display panel includes an aperture area, a partition area surrounding the aperture area, a display area surrounding the partition area, a substrate, and at least one isolation pillar disposed on a first side of the substrate. The isolation pillar is disposed in the partition area and disposed around the aperture area, the isolation pillar includes a first metal layer, the first metal layer includes a first metal material and a conductive structure disposed on a side of the first metal layer away from the substrate, and the conductive structure overlaps with the first metal layer. The conductive structure includes a first conductive material, electron-accepting ability of the first conductive material is greater than electron-accepting ability of silver ions and electron-accepting ability of the first metal material.

### CROSS-REFERENCE TO RELATED APPLICATION

This application claims priority to Chinese Patent Application No. 202410867070.0, filed on Jun. 28, 2024, which is hereby incorporated by reference in its entirety.

### TECHNICAL FIELD

The present application relates to the technical field of display, and in particular to a display panel and a display device.

### BACKGROUND

Organic Light-Emitting Diode (OLED) display device is a promising display technology due to the advantages of thinness, lightness, fast response speed, low energy consumption, high luminous efficiency and flexible display. With the increasing demands of users on products and the fierce competition in the industry, OLED display device is pursuing higher screen-to-body ratios in order to bring stronger visual impact to users.

In existing technologies, sensors such as cameras are placed in the screen and the apertures are formed on the screen. The current OLED display panels with apertures have the problem of encapsulation failure.

### SUMMARY

Embodiments of the present application provide a display panel and a display device to prevent an OLED display panel from forming a water oxygen intrusion pathway.

In a first aspect, embodiments of the present application provide a display panel. The display panel includes an aperture area, a partition area surrounding the aperture area, a display area surrounding the partition area, a substrate, and at least one isolation pillar disposed on a first side of the substrate. The isolation pillar is disposed in the partition area and disposed around the aperture area, the isolation pillar includes a first metal layer, the first metal layer includes a first metal material and a conductive structure disposed on a side of the first metal layer away from the substrate, and the conductive structure overlaps with the first metal layer in a direct perpendicular to the substrate. The conductive structure includes a first conductive material, the electron-accepting ability of the first conductive material is greater than the electron-accepting ability of silver ions, and the electron-accepting ability of the first conductive material is greater than the electron-accepting ability of the first metal material.

In a second aspect, embodiments of the present application provide a display device, and the display device includes the display panel provided in any of the embodiments of the present application.

In embodiments of the present application, a display panel is provided with an aperture area and a partition area is provided between a display area and the aperture area. A plurality of isolation pillars are provided in the partition area, and the isolation pillars include a first metal layer including a first metal material. In embodiments of the present application, there is further provided a conductive structure which at least partially overlaps with the first metal layer in a direction perpendicular to the substrate. Because the electron-accepting ability of the first conductive material in the conductive structure is greater than the electron-accepting of the silver ions, thereby reducing the probability that the electrons released from the first metal material are acquired by the silver ions in the etching solution when the first metal layer is etched, thereby avoiding the formation of silver metal particles on the isolation pillars, and then avoiding the formation of a water vapor intrusion pathway due to the poor coverage of encapsulation structure at the metal particles, contributing to improving the reliability of the display panel, and significantly increasing the process yield of the display panel.

### BRIEF DESCRIPTION OF THE DRAWINGS

FIG. 1 is a structural schematic view of a display panel according to an embodiment of the present application;

FIG. 2 is a partially enlarged schematic view of the display panel shown in FIG. 1;

FIG. 3 is a cross-sectional view of the display panel along a line b-b′ shown in FIG. 2;

FIG. 4 is a cross-sectional view of another display panel along a line b-b′ shown in FIG. 2;

FIG. 5 is a cross-sectional view of a partition area according to an embodiment of the present application;

FIG. 6 is a cross-sectional view of another partition area according to an embodiment of the present application;

FIG. 7 is a cross-sectional view of another partition area according to an embodiment of the present application;

FIG. 8 is a cross-sectional view of another partition area according to an embodiment of the present application;

FIG. 9 is a cross-sectional view of another partition area according to an embodiment of the present application;

FIG. 10 is a structural schematic view of a partition area according to an embodiment of the present application;

FIG. 11 is a structural schematic view of another partition area according to an embodiment of the present application;

FIG. 12 is a cross-sectional view of another partition area according to an embodiment of the present application;

FIG. 13 is a cross-sectional view of another partition area according to an embodiment of the present application;

FIG. 14 is a cross-sectional view of another display panel along a line b-b′ shown in FIG. 2;

FIG. 15 is a cross-sectional view of another display panel along a line b-b′ shown in FIG. 2;

FIG. 16 is a structural schematic view of an electronic device according to an embodiment of the present application.

### DETAILED DESCRIPTION

The present application is described in further detail below in connection with the accompanying drawings and embodiments. It is to be understood that the specific embodiments described herein are for the purpose of explaining the present application only and are not intended to limit the present application. It is also to be noted that, for ease of description, only parts relevant to the present application, but not the entire structure, are shown in the accompanying drawings.

In the related art, the display panel includes an aperture area for setting some sensors such as a camera. The aperture area is prone to form a water oxygen intrusion pathway. In the related art, the possibility of water oxygen intrusion is reduced by providing a dam portion around the aperture area. However, in the process of realizing the present application, it is found that the display panel provided with the dam portion is still prone to form a water oxygen intrusion pathway. The formation of the water oxygen intrusion pathway leads to the occurrence of peeling in part of the film layers of the display panel, which ultimately leads to the appearance of colored striae, also known as rainbow patterns, in the screen area near the aperture when the screen area is viewed.

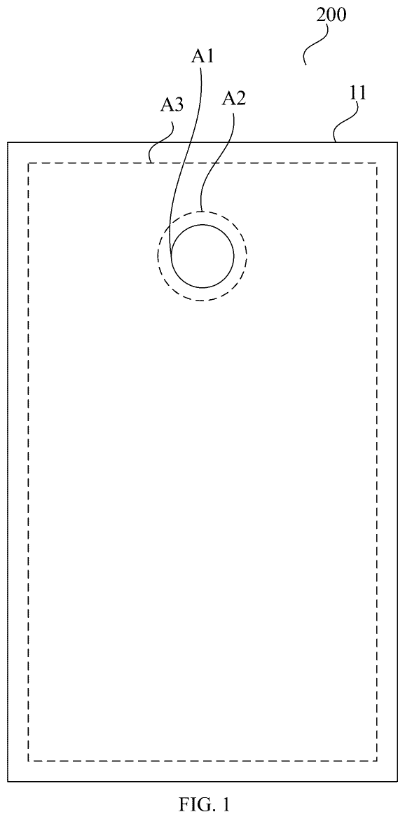

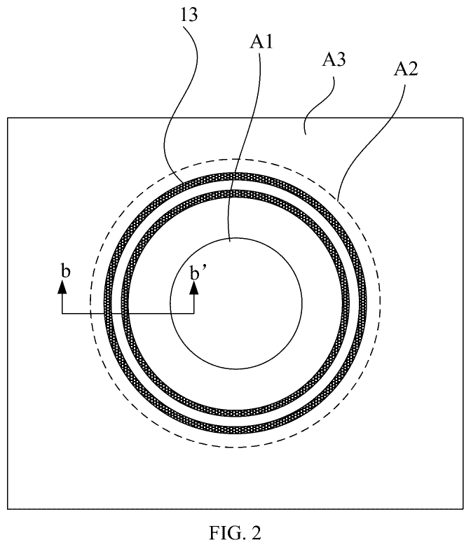

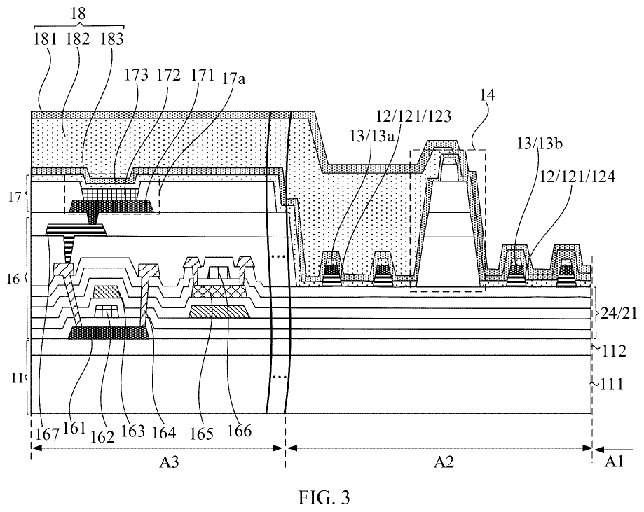

In order to further reduce the formation of the water oxygen intrusion pathway, embodiments of the present application provide a display panel as shown in FIGS. 1 to 3. FIG. 1 is a schematic view of a display panel according to an embodiment of the present application, FIG. 2 is a partially enlarged schematic view of the display panel shown in FIG. 1, and FIG. 3 is a cross-sectional view of the display panel along a line b-b′ shown in FIG. 2. The display panel includes an aperture area A1; a partition area A2 surrounding the aperture area A1; a display area A3 surrounding the partition area A2; a substrate 11; at least one isolation pillar 12 disposed on a first side of the substrate 11 and disposed in the partition area A2 and around the aperture area A1, the isolation pillar 12 including a first metal layer 121 that includes a first metal material; and a conductive structure 13 disposed on a side of the first metal layer 121 away from the substrate 11. In a direction perpendicular to the substrate 11, the conductive structure 13 overlaps with the first metal layer 121.

The conductive structure 13 includes a first conductive material, the electron-accepting ability of which is greater than that of silver ions and is also greater than that of the first metal material.

FIG. 3 shows a film layer structure of a display panel, the display panel may include a substrate 11, or may also include a driving circuit layer 16, a light emitting device layer 17, and an encapsulation layer 18 on the substrate 11. The substrate 11 may be a single layer or a multilayer structure; for example, the substrate 11 may include a glass base plate 111 and a buffer layer 112 on the glass base plate 111, or the substrate 11 may include a polyimide and a buffer layer on the polyimide. The material of the buffer layer 112 may include silicon nitride and silicon oxide, and the like. The driving circuit layer 16 includes a multilayer metal layers capable of forming an array of pixel driving circuits. Exemplarily, in a direction away from the substrate 11, the driving circuit layer 16 includes a first active layer 161, a first gate layer 162, a first electrode plate layer 163, a second active layer 165, a second gate layer 166, a source-drain metal layer 164, and an auxiliary connecting layer 167, that is, the display panel may be a Low Temperature Polycrystalline Oxide (LTPO) display panel. In addition, the display panel may also be a Low Temperature Poly-Silicon (LTPS) display panel, and then the film layer included in the driving circuit layer 16 of the display panel is different from the film layer in FIG. 3. The specific type of the display panel of the present embodiment is not specifically limited, and in the present embodiments of the present application, only the LTPO display panel is taken as an example for illustration. In the driving circuit layer 16, the electrical isolation may be realized between the above two adjacent film layers by means of an insulating layer 21. The light emitting device layer 17 includes emitting devices 17a arranged in an array that may include an anode 171, an organic material layer 172, and a cathode 173. A voltage difference is formed between the anode 171 and the cathode 173, enabling the electroluminescent organic light emitting material of the organic material layer 172 to emit light of a corresponding color under the action of the above voltage difference. The pixel driving circuit of the driving circuit layer 16 is capable of providing a driving current for the corresponding light emitting device 17a to enable the corresponding light emitting device to emit light. One side of the light emitting device layer 17 away from the substrate 11 is also provided with an encapsulation layer 18, and the encapsulation layer 18 has the effect of blocking water vapor, oxygen, and impurities in air to protect the film layer structure inside the display panel. The encapsulation layer 18 may include an organic layer and an inorganic layer disposed alternately. The organic layer is made of an organic material having high fluidity. Exemplarily, optionally, the encapsulation layer 18 includes a first inorganic encapsulation layer 183, a first organic encapsulation layer 182, and a second inorganic encapsulation layer 181 away from the substrate 11 in sequence.

As shown in FIGS. 1 to 3, the display panel includes a display area A3 and an aperture area A1 formed within the display area A3. The aperture area A1 includes a through-hole penetrating through the display panel for setting a predetermined element such as a camera, a sensor, and the like. A partition area A2 is formed between the display area A3 and the aperture area A1. The partition area A2 is provided with isolation pillars 12. In the above example, the materials of the first inorganic encapsulation layer 183 and the second inorganic encapsulation layer 181 may include silicon nitride, silicon oxide, alumina, or the like, and the first inorganic encapsulation layer 183 and the second inorganic encapsulation layer 181 extend from the display area A3 through the entire partition area A2. The material of the first organic encapsulation layer 182 may include epoxy resin, acrylic resin, silicon oxycarbide, or the like, and the first organic encapsulation layer 182 extends from the display area A3 through part of the partition area A2 and is blocked by the dam portion 14. Then the encapsulation layer 18 can block the water oxygen intrusion pathway formed by the aperture area A1 and improve the display effect.

In a direction perpendicular to the display panel, the display panel includes a substrate 11, isolation pillars 12 and conductive structures 13, and the isolation pillars 12 and conductive structures 13 face away from the substrate 11 in sequence.

The isolation pillars 12 are formed on the first side of the substrate 11; of course, as shown in FIG. 3, a plurality of metal or non-metal layers may be provided between the isolation pillars 12 and the substrate 11. The isolation pillar 12 includes at least the first metal layer 121. That is, the isolation pillar 12 may be formed by only the first metal layer 121 or may be formed by stacking the first metal layer 121 and other structural layers, and the present embodiments do not specifically limit this. The conductive structure 13 is provided on a side of the isolation pillar 12 away from the substrate 11, and in a direction perpendicular to the substrate 11, the conductive structure 13 overlaps with the first metal layer 121.

The conductive structure 13 includes a first conductive material, the electron-accepting ability of the first conductive material is greater than the electron-accepting ability of silver ions, and the electron-accepting ability of the first conductive material is greater than the electron-accepting ability of the first metal material. The electron-accepting ability, also known as oxidizing ability, is the ability of an atom, molecule, or ion to get electrons. In the manufacturing process of the display panel, specifically, in the process of preparing the individual metal layers of the driving circuit layer 16 and the anode 171 of the light emitting device layer 17, a corresponding patterned structure needs to be prepared. Exemplarily, in preparing the patterned structure of a certain layer of metal, a sputtering process or an evaporation process may be used to form a full-layered metal film layer, a photoresist is coated on the metal film layer, a mask is used for exposing and developing the photoresist, after which an etching process is used for etching the metal film layer, and finally the remaining photoresist on the metal film layer is peeled off. The acidic etching solution used in the present application may be a mixture of phosphoric acid, nitric acid, acetic acid, and hydrochloric acid, and a pH value of the mixture can reaches to 2 to 3. Optionally, the first metal material may include any one of titanium (Ti), aluminum (Al), molybdenum (Mo), copper (Cu), iron (Fe), nickel (Ni), and chromium (Cr). The anode 171 may include indium tin oxide (ITO), silver (Ag), and the like. Exemplarily, the silver ions (Ag⁺) are easily generated and exist in the acidic etching solution when the argentum (Ag) in the anode 171 contacts with the acidic etching solution.

Referring to the display panel in the present embodiment shown in FIG. 3, the isolation pillars 12 contain the first metal material, and preparation of the anode 171 is performed after the isolation pillars 12 are formed. During etching to form the anode 171, the acidic etching solution reacts with the anode material to produce silver ions (Ag⁺). In a situation where no conductive structure 13 is provided on the isolation pillar 12, when the prepared isolation pillar 12 is side-etched, the silver ions (Ag⁺) get electrons from the first metal material and form metal silver particles that adhere to the surface of the isolation pillar 12 because the electron-accepting ability of the silver ions (Ag⁺) in the acidic etching solution is greater than that of the first metal material. At this time the first inorganic encapsulation layer 183 is prone to be peeled off, resulting in poor flatness of the subsequently manufactured film layer, and thus poor encapsulation is likely to occur when the display panel is encapsulated, causing the encapsulation layer to form a water vapor intrusion pathway and reducing the reliability of the display panel. It should be noted that in the present embodiment, one side of the isolation pillar 12 away from the substrate 11 is provided with a conductive structure 13. The conductive structure 13 contains a first conductive material, and the first conductive material is easier to get electrons than silver ions. In the present embodiment, during the formation of the anode 171, silver ions (Ag⁺) appear in the acidic etching solution, and then after that, side engraving is carried out on the isolation pillar 12, and aluminum (Al) easily loses electrons in the acidic etching solution, but at this time, on the isolation pillar 12 is provided a conductive structure 13 containing the first conductive material, and because the first conductive material is easier to get electrons than the silver ions (Ag⁺), the metal particles Ag cannot be formed. Under the action of the conductive structure 13, the isolation pillar 12 can maintain a relatively smooth and flat structure, avoid the influence of metal particles on the subsequent encapsulation effect, and improve the process yield of the display panel.

Exemplarily, the first metal material 122 may be aluminum (Al). In the prior art, the etching solution includes silver ions (Ag⁺), and aluminum (Al) is prone to lose electrons in the etching solution that is acidic. The chemical reaction formula is shown in (Eq. 1):

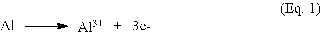

Silver ions (Ag⁺) easily undergo a reduction reaction on the surface of the isolation pillars 12, producing metal particles that adhere to the surface of the isolation pillars 12. The chemical reaction formula for the silver ion (Ag⁺) to get electrons is shown in (Eq. 2):

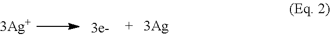

In the present embodiment of the present application, due to the presence of the conductive structure 13, the specific process is as follows: aluminum (Al) is prone to lose electrons in the acidic etching solution, and the chemical reaction formula is shown in (Eq. 3):

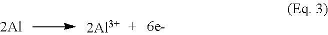

Since the electron-accepting ability of the first conductive material is greater than that of silver ions, the first conductive material is easier to get electrons than silver ions; optionally, in the present embodiment, the material of the conductive structure 13 may include at least one of indium oxide, zinc oxide, tin oxide, or gallium oxide, all of which are strongly oxidative. In addition to that, the conductive structure 13 may include a mixture of at least two of indium oxide, zinc oxide, tin oxide, and gallium oxide; for example, the conductive structure 13 may include indium tin oxide or indium zinc oxide. Furthermore, the conductive structure 13 may be a stacked structure including the above materials, for example, a stacked structure of ITO/Ag/ITO, which is not specifically limited by the present embodiment. The present embodiment is illustrated by taking indium tin oxide (ITO) for example, which is a mixture of indium oxide (In₂O₃) and tin oxide (SnO₂) and has a good conductivity. In the present embodiment, the first conductive material may be indium oxide (In₂O₃), and indium oxide (In₂O₃) is easier to get electrons than silver ions (Ag⁺), so silver ions (Ag⁺) is not easy to get electrons. Part of the indium oxide (In₂O₃) undergoes a reduction reaction, and the chemical reaction formula for indium oxide (In₂O₃) to get electrons is shown in (Eq. 4):

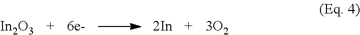

Because the formed elemental In, unlike Ag, cannot form large metal particles, there is no or little influence on the smoothness of the surface of the conductive structure 13 and thus no or little influence on the encapsulation layer. Therefore, in the present embodiment, the conductive structure 13 can effectively inhibit the reduction reaction of silver ions on the surface of the isolation pillars 12. The surfaces of the conductive structure 13 and the isolation pillar 12 can remain relatively smooth and flat, avoiding the problem that the subsequently manufactured film layer has poor flatness and is prone to form a water vapor intrusion pathway.

Continuing to refer to FIG. 3, optionally, the display panel may further include a driving circuit layer 16 and a light emitting device layer 17, the light emitting device layer 17 includes an anode 171, an organic material layer 172, and a cathode 173, and the conductive structure 13 is of the same material as the anode 171.

Exemplarily, in the LTPO display panel, the driving circuit layer 16 specifically includes a first active layer 161, a first gate layer 162, a first electrode plate layer 163, a second active layer 165, a second gate layer 166, a source-drain metal layer 164, and an auxiliary connecting layer 167. The first metal layer 121 and the auxiliary connecting layer 167 may be disposed on the same layer, so that the isolation pillar 12 is disposed without the need for an additional process, saving process complexity and enhancing panel production efficiency. In addition, the conductive structure 13 and the anode 171 are disposed on the same layer, so that in the present embodiment, without additional process on the display panel, the conductive structure 13 can be formed on the isolation pillar 12, the effect of a smooth surface of the isolation pillar 12 can be achieved, the cracks formed on the encapsulation layer due to the metal particles on the isolation pillars 12 is avoided, and the quality of the display panel is improved.

In one embodiment of the present application, the display panel is provided with an aperture area, and a partition area is provided between the display area and the aperture area. A plurality of isolation pillars are provided in the partition area, and each of the plurality of isolation pillars include a first metal layer containing a first metal material. The present application is also provided with a conductive structure, and the conductive structure is at least partially overlapped with the first metal layer in a direction perpendicular to the substrate. Because the electron-accepting ability of the first conductive material in the conductive structure is greater than electron-accepting ability of the silver ions, thereby reducing the probability that the electrons released from the first metal material are acquired by the silver ions in the etching solution when the first metal layer is etched, thereby avoiding the formation of silver metal particles on the isolation pillars, and consequently thereby avoiding the formation of a water vapor intrusion pathway due to the poor coverage of the encapsulation structure at the metal particles, which contributes to improving the reliability of the display panel and significantly increases the process yield of the display panel.

Optionally, the conductive structure 13 may be electrically connected to the first metal layer 121. Continuing to refer to FIG. 3, the conductive structure 13 is electrically connected to the first metal layer 121, and because the electron-accepting ability of the first conductive material is greater than electron-accepting ability of the first metal material, the first conductive material of the conductive structure 13 can quickly get electrons when the first metal material in the first metal layer 121 loses electrons, effectively avoiding the silver ions in the acidic etching solution (Ag⁺) from acquiring electrons to form metal particles, further enhancing the smoothness of the surface of the isolation pillars 12, effectively preventing the intrusion of water vapor, thereby avoiding the situation in which a rainbow pattern exists in the display panel product due to the metal precipitation on the isolation pillars 12, and enhancing the process reliability of the display panel.

Optionally, the conductive structure 13 is in direct contact with the first metal layer 121. As shown in FIG. 3, in the present embodiment, the conductive structure 13 is controlled to be direct contact with the surface of the first metal layer 121 away from the substrate 11. Then the contact area between the conductive structure 13 and the first metal layer 121 is larger, and the electrons released from the first metal material in the first metal layer 121 cannot be acquired by the silver ions in the etching solution, but can be quickly acquired by the first conductive material of the conductive structure 13. In the present embodiment, the silver ions is not easy to precipitate out metal particles on the isolation pillars, thereby avoiding the formation of water vapor intrusion pathways due to poor coverage of the encapsulation structure at the metal particles, which enables the encapsulation structure to has a good encapsulation effect on the display panel, and is conducive to improving the reliability of the display panel.

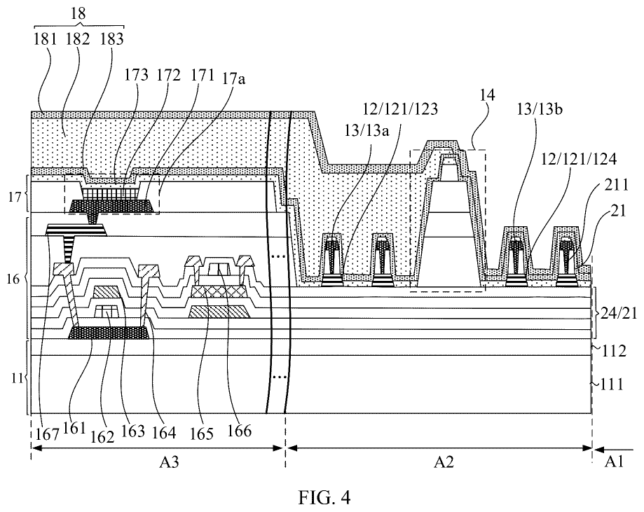

FIG. 4 is a cross-sectional view of another display panel along a line b-b′ shown in FIG. 2. Optionally, the conductive structure 13 is connected to the first metal layer 121 through a via 211. In the present embodiment, at least one insulating layer 21 may be provide between the conductive structure 13 and the first metal layer 121, and a via 211 is formed in the insulating layer 21 on the first metal layer 121 to enable the conductive structure 13 to electrically connect to the first metal layer 121 through the via 211. A stacked structure is formed from the insulating layer 21 on the isolation pillar 12 together with the isolation pillar 12, effectively blocking the organic material layer of the light emitting device layer 17, avoiding damage to the organic material layer when water vapor intrudes, and effectively enhancing the reliability of the display panel.

Still referring to FIGS. 3 and 4, optionally, the partition area A2 is provided with a dam portion 14, a plurality of inner isolation pillars 123 are provided between the dam portion 14 and the display area A3, and the conductive structure includes a first conductive structure disposed on at least one of the inner isolation pillars 123.

In the present embodiment, the partition area A2 may also be provided with a dam portion 14, and the dam portion 14 may be formed by stacking multilayer insulating layers of the display panel, part of which may be removed from the partition area A2 other than the dam portion 14. An inner partition area is formed between the dam portion 14 and the display area A3, and it may be used for setting the inner isolation pillars 123. Optionally, one side of the dam portion 14 away from the substrate 11 is further provided with an encapsulation layer 18, and the encapsulation layer 18 has a technical effect of blocking water vapor, oxygen, and impurities in air, which may protect the film layer structure inside the display panel. The encapsulation layer 18 may include an organic layer and an inorganic layer disposed alternately. The organic layer is made of an organic material having high fluidity, and the arrangement of the dam portion 14 can effectively prevent the overflow of the organic material. Optionally, the encapsulation layer 18 includes a first inorganic encapsulation layer 183, a first organic encapsulation layer 182, and a second inorganic encapsulation layer 181 away from the substrate 11 in sequence. The first inorganic encapsulation layer 183 and the second inorganic encapsulation layer 181 extend from the display area A3 to the inner partition area, and then to an outer partition area formed between the dam 14 and the aperture area A1 and configured to set the outer isolation pillars 124; the first organic encapsulation layer 182 extends from the display area A3 to the inner partition area and is blocked by the dam 14. Because the first organic encapsulation layer 182 is made of an organic material having high fluidity, and the arrangement of the dam portion 14 can effectively prevent the overflow of the organic material. Optionally, in a plane parallel to the substrate 11, the dam portion 14 may form a closed structure around the aperture area A1. In the present embodiment, a first conductive structure 13a is provided on the side of the inner isolation pillar 123 away from the substrate 11. Then a smooth and flat structure is formed on the side of the inner isolation pillar 123 away from the substrate 11, and there is no precipitation of metal particles on the surface so as to enhance the process yields of the subsequent film layers such as the encapsulation layer and improve the encapsulation effect of the display panel, and avoid cracks on the encapsulation layer for providing an intrusion path for the water oxygen, thus improving the reliability of the display panel.

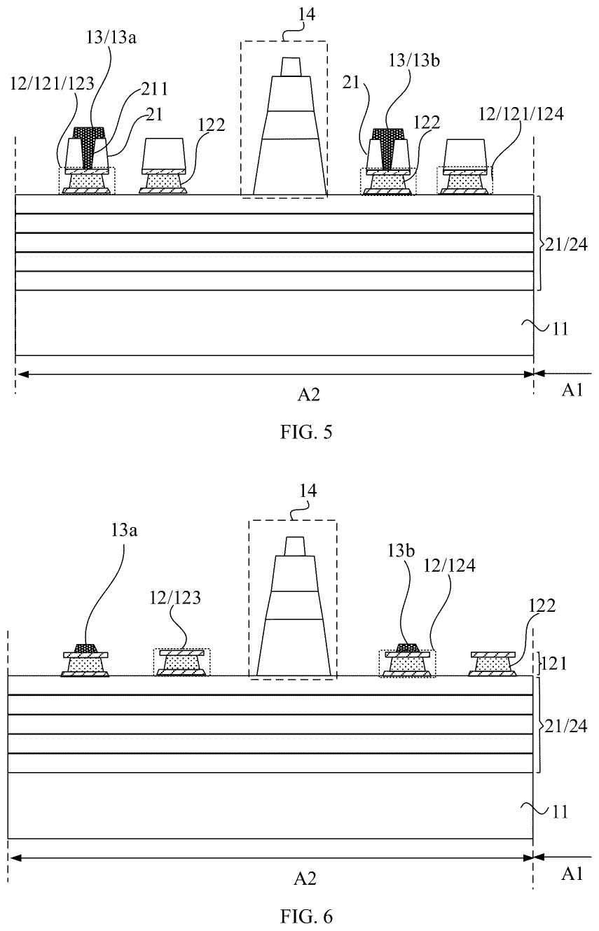

In the present embodiment, each of the inner isolation pillars 123 can be provided with a first conductive structure 13a, so as to quickly and effectively protect the inner isolation pillars 123, prevent metal particles of Ag from adhering to the surfaces of the inner isolation pillars 123, thereby preventing water oxygen from intruding into the encapsulation layer to affect the display effect of the display panel. FIG. 5 is a cross-sectional view of a partition area according to an embodiment of the present application, and FIG. 6 is a cross-sectional view of partition area according to another embodiment of the present application. In order to facilitate the illustration of the specific structure of the isolation pillars 12 and the conductive structures 13, the structures of the light emitting device layer 17 and the encapsulation layer 18 are not shown in FIGS. 5 and 6. As shown in FIGS. 5 and 6, in the present embodiment, the first conductive structures 13a are provided on the side of the first metal layer 121 of only part of inner isolation pillars 123 away from the substrate 11. Exemplarily, the closer the isolation pillar 12 is to the aperture area A1, the less it is affected by the silver ions in the acidic etching solution (Ag⁺); the closer the inner isolation pillar 123 is to the display area A3, the more it is affected by the acidic etching solution. The first conductive structures 13a may be provided on the first metal layers 121 of the inner isolation pillars 123 close to the display area A3, and no first conductive structure 13a is provided on the inner isolation pillars 123 away from the display area A3.

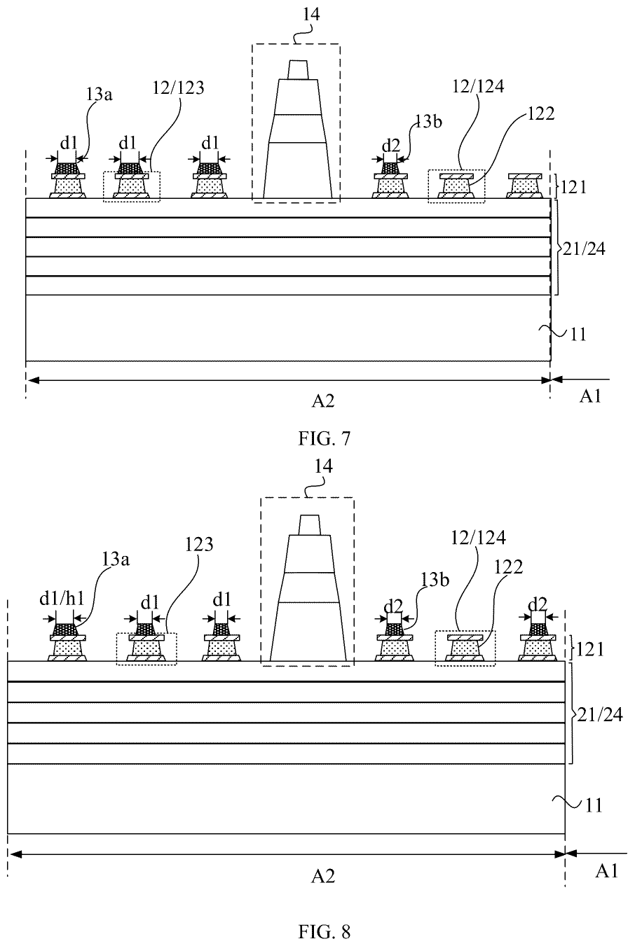

FIG. 7 is a cross-sectional view of another partition area according to an embodiment of the present application. Optionally, there are more than two first conductive structures 13a which are disposed on different inner isolation pillars 123 and each have the same width d1 on the inner isolation pillars 123.

In the present embodiment, the more than two first conductive structures 13a may be provided in the inner isolation area, and three first conductive structures 13a are illustrated in FIG. 7 as an example. Each of first conductive structures 13a is disposed on a different inner isolation pillars 123, then it is not easy for the silver ions near the inner isolation pillars 123 to be precipitated as metal particles on the inner isolation pillars 123, thereby avoiding the formation of water vapor intrusion pathways due to poor coverage of the encapsulation structure at the metal particles, and enabling the encapsulation structure to encapsulate the display panel effectively. Optionally, in the direction from the partition area A2 to the aperture area A1, the widths d1 of the first conductive structures 13a on the inner isolation pillars 123 are all equal, so that the first conductive structures 13a can uniformly protect each of inner isolation pillars 123, avoiding the precipitation of metal particles on the surface of the inner isolation pillars 123.

FIG. 8 is a cross-sectional view of another partition area according to an embodiment of the present application; optionally, there are more than two first conductive structures 13a, which are disposed on different inner isolation pillars 123, respectively, and the widths d1 of which on the inner isolation pillars 123 are different and gradually decrease in the direction from the display area A3 to the aperture area A1. Similarly, three first conductive structures 13a are illustrated in FIG. 8 as an example. Each of the first conductive structures 13a is disposed on a different inner isolation pillar 123, so it is not easy for the silver ions near the inner isolation pillars 123 to be precipitated as the metal particles on the inner isolation pillars 123. Because the closer it to the display area A3, the greater the concentration of the silver ions in the acidic etching solution, then the widths d1 of first conductive structures 13a in the direction from the partition area A2 toward the aperture area A1 may be set greater and greater as it becomes closer and closer to the display area A3, and the widths d1 of the first conductive structures 13a in the direction from the partition area A2 toward the aperture area A1 may be set smaller and smaller as it becomes farther and farther away from the display area A3, so as to enhance the protection for the inner isolation pillars 123 close to the display area A3, effectively preventing the precipitation of metal particles on the surface of inner isolation pillars 123, avoiding the cracks on the subsequent encapsulation layer due to the presence of metal particles, and enhancing the reliability of the display panel.

Still referring to FIGS. 5 to 8, optionally, the outer isolation pillars 124 are provided between the dam portion 14 and the aperture area A1, the conductive structure includes a second conductive structure 13b provided on the side of at least one of the outer isolation pillars 124 away from the substrate 11. In the present embodiment, the inner isolation area is formed between the dam portion 14 and the display area A3, and it can be used for setting the inner isolation pillars 123. The outer isolation area is formed between the dam portion 14 and the aperture area A1, and it can be used for setting the outer isolation pillars 124. A first conductive structure 13a is provided on the side of the inner isolation pillar 123 away from the substrate 11, and a second conductive structure 13b is provided on the side of the outer isolation pillar 124 away from the substrate 11. A smooth and flat structure can be formed on the side of the isolation pillar 12 away from the substrate 11, and there is no precipitation of metal particles on the surface of the isolation pillar 12 so as to enhance the process yields of the subsequent film layers and improve the reliability of the display panel. Continuing to refer to FIG. 8, optionally, the second conductive structures 13b are spaced apart. In the present embodiment, the outer isolation pillars 124 in the outer partition area are farther away from the display area A3 than the inner isolation pillars 123 in the inner partition area and do not have much effect on the display effect of the display panel. The number of the second conductive structures 13b may be less than the number of the first conductive structures 13a, and then the second conductive structures 13b may be spaced apart on the outer isolation pillars 124. Exemplarily, in the direction from the partition area A2 toward the aperture area A1, the second conductive structures 13b are provided on the odd-numbered outer isolation pillars 124, and no second conductive structures 13b are provided on the even-numbered outer isolation pillars 124, so that on the one hand, the arrangement density of the second conductive structures 13b can be reduced, thereby reducing the difficulty of the process; on the other hand, the second conductive structure 13b is disposed uniformly to effectively provide protection for the nearby outer isolation pillars 124, preventing the silver ions in the acidic etching solution from being reduced to generate silver particles, maintaining the smoothness of the surface of the outer isolation pillars 124, effectively ensuring the encapsulation effect of the partition area A2, avoiding the rainbow pattern phenomenon caused by encapsulation cracks, and effectively avoiding the damage caused by water oxygen intrusion to the organic material layer of the display panel, and enhancing the display effect of the display panel.

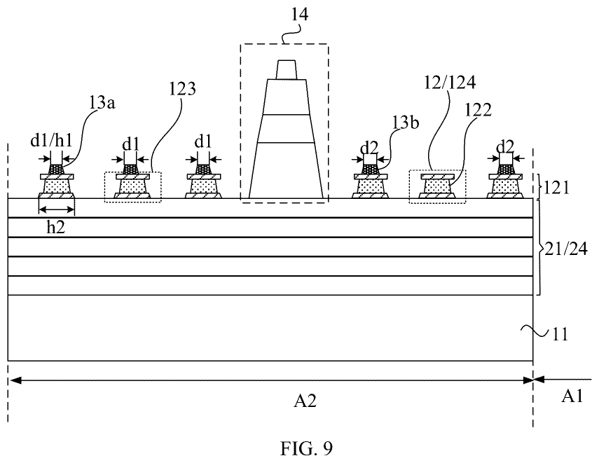

FIG. 9 is a cross-sectional view of another partition area according to an embodiment of the present application, as shown in FIG. 9, optionally, the second conductive structure 13b and the first conductive structure 13a have the same width. The inner isolation pillar 123 is provided with the first conductive structure 13a, and the outer isolation pillar 124 is provided with the second conductive structure 13b. In the present embodiment, in the direction from the isolation area A2 to the aperture area A1, the width of the first conductive structure 13a is d1 and the width of the second conductive structure 13b is d2, where d1 can be set equal to d2. Then the first conductive structures 13a and the second conductive structures 13b are capable of quickly get electrons to avoid the silver ions in the surrounding acidic etching solution from getting electrons to form metal particles, and at the same time to enhance the smoothness of the surfaces of the inner isolation pillars 123 and the outer isolation pillars 124, avoiding the problem that the subsequently manufactured film layer is poorly flat and prone to forming water vapor intrusion pathway.

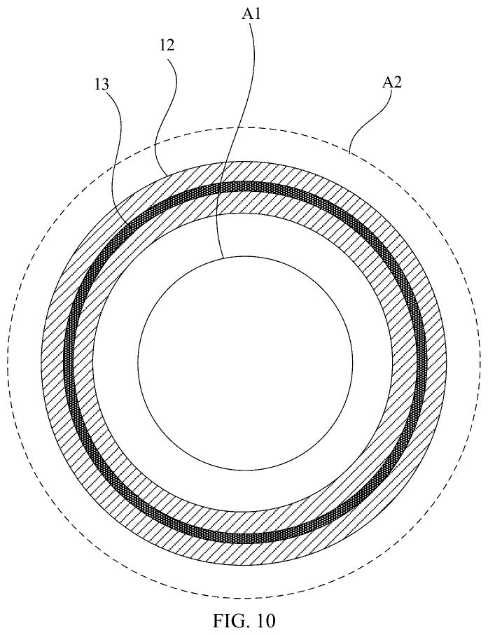

FIG. 10 is a schematic view of a partition area according to an embodiment of the present application. Optionally, viewed in a direction perpendicular to the substrate 11, the conductive structure 13 forms a ring on the same isolation pillar 12. Because the isolation pillar 12 is a closed structure surrounding the aperture area A1, when the conductive structure 13 is provided on the isolation pillar 12, the conductive structure 13 may likewise be provided around the aperture area A1. The conductive structure 13 may be formed in the shape of a ring, and it should be noted that, as shown in FIG. 10, the ring in the present embodiment may be a standard ring-shaped continuous structure or a ring-like continuous structure. In addition, the conductive structure 13 may be a non-continuous structure, and the non-continuous structure is formed in a distributed ring around the aperture area A1 on the isolation pillar 12. In the present embodiment, the conductive structure 13 can be uniformly provided around the top surface of the isolation pillar 12, and can effectively protect the surface of the isolation pillar 12 corresponding to the conductive structure 13. Specifically, in the acidic etching solution, the first conductive material of the conductive structure 13 can get the electrons lost by the first metal material of the isolation pillar 12, so that the silver ions in the acidic etching solution will not get electrons to form metal particles to adhere to the surface of the isolation pillar 12, and one side of the isolation pillar away from the substrate 11 will form a smooth and flat structure, enhancing the encapsulation effect of the display panel, avoiding cracks on the encapsulation layer to provide an intrusion path for water oxygen, thereby further enhancing the reliability of the display panel.

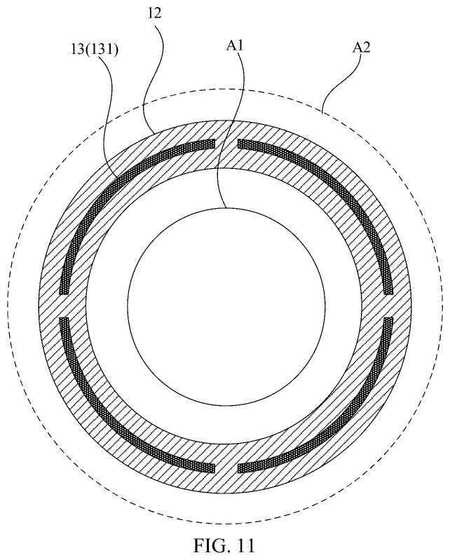

FIG. 11 is a schematic view of another partition area according to an embodiment of the present application. Optionally, viewed in the direction perpendicular to the substrate 11, the conductive structure 13 includes a plurality of conductive sub-structures 131 disposed non-continuously, and the plurality of conductive sub-structures 131 are disposed in sequence on the same isolation pillar 12. When the conductive structure 13 is a non-continuous structure, the conductive structure 13 may include a plurality of conductive sub-structures 131, which are disposed in sequence to form a ring around the aperture area A1. In the present embodiment, it is possible to avoid forming metal particles of Ag on the side of the isolation pillar 12 away from the substrate 11, prevent cracks on the encapsulation layer and improve the process yield of the display panel. Optionally, as shown in FIG. 9, the spacing between two adjacent conductive sub-structures 131 is the same, so that the sub-conductive structures 131 on the side of the isolation pillars 12 away from the substrate 11 are disposed uniformly, further improving the flatness of the surface of the isolation pillar 12 and avoiding the formation of a water vapor intrusion pathway in the encapsulation layer.

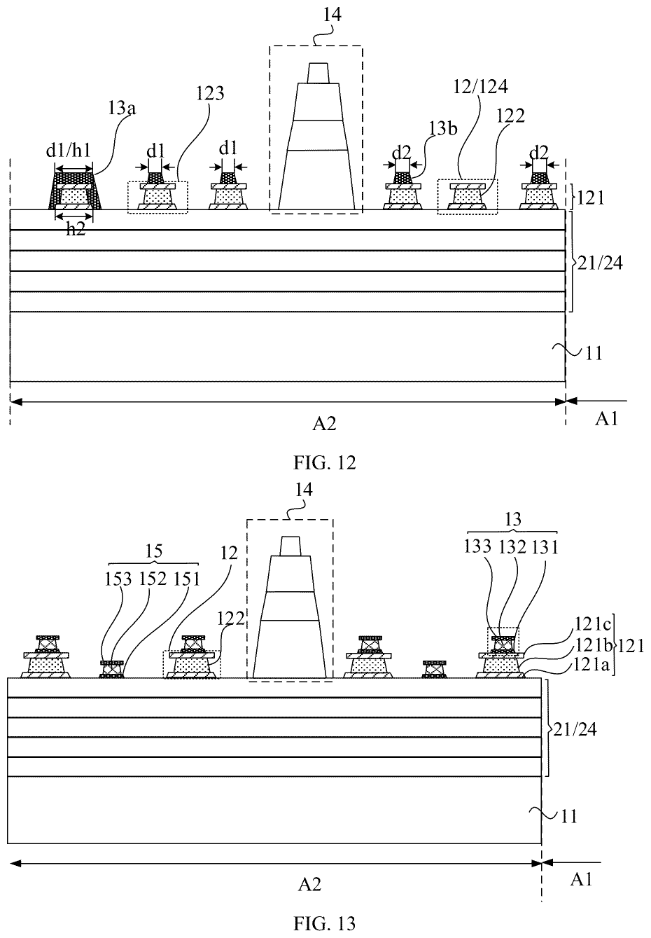

Optionally, 3 um≤h1≤h2, or, 3 um≤h2<h1, where h1 is a width of the conductive structure 13 in the direction from the aperture area A1 to the display area A3, and h2 is a width of the first metal layer 121 in the direction from the aperture area A1 to the display area A3. In the present embodiment, the conductive structure 13 is provided on the first metal layer 121 and is electrically connected to the first metal layer 121. Set as a width of the conductive structure 13 in the direction from aperture area A1 toward the display area A3, h1 may refer to a width of the conductive structure 13 on the inner isolation pillar 123 or a width of the conductive structure 13 on the outer isolation pillar 124, and h1 is a variable. Set as the width of the first metal layer 121 in the direction from the aperture area A1 to the display area A3, h2 has a specific value. In the first case, as shown in FIG. 6, the width h1 of the conductive structure 13 may be less than or equal to the width h2 of the first metal layer 121 in the direction from the aperture area A1 to the display area A3, and when the conductive structure 13 is provided on the first metal layer 121, the maximum value of the width h1 of the conductive structure 13 is h2; in a case where the conductive structure 13 is in direct contact with the first metal layer 121, the conductive structure 13 has the largest contact area with the first metal layer 121, which can effectively ensure the surfaces of the isolation pillars to form a smooth and flat structure, and enhance the process yield of the subsequent film layer. In the second case, as shown in FIG. 12 which is a cross-sectional view of another partition area according to an embodiment of the present application, the width h1 of the conductive structure 13 may be larger than the width h2 of the first metal layer 121, so part of the conductive structure 13 is provided on the sidewalls of the first metal layer 121, thereby increasing the area for setting the conductive structure 13. The conductive structure 13 with a larger width can further consume the electrons lost by the first metal material in the acidic etching solution, reduce the possibility of the silver ions being reduced to elemental silver, further enhance the smoothness of the surface of the isolation pillar 12, enhance the process yields of the subsequent film layers, and further enhance the quality of the display panel. In the present embodiment, the conductive structure 13 and the isolation pillar 12 have a minimum width of 3 um. Because the minimum width achievable by the process is 3 μm, the minimum value of the width h1 of the conductive structure 13 is limited by the process precision, and the width h1 of the conductive structure 13 in the present embodiment is 3 um≤h1≤h2. Of course, with the development of the process precision, when the process precision can be developed to a smaller size, such as 2 μm, the minimum value of the width h1 of the conductive structure 13 may be 2 um, then the width h1 of the conductive structure 13 in the present embodiment may be 2 um≤h1≤h2. In the present embodiment, the width h1 of the conductive structure 13 can take a value within any of the above value ranges to consume the electrons lost by the first metal material in the acidic etching solution, avoid the precipitation of Ag metal particles on the surfaces of the isolation pillars, avoid encapsulation failure, and block the subsequent encapsulation layer from forming water vapor intrusion pathways.

Optionally, the material of the conductive structure 13 may include indium tin oxide or indium zinc oxide. In the present embodiment, the material of the conductive structure 13 may be a mixture of at least two oxides such as indium tin oxide or indium zinc oxide. Exemplarily, the conductive structure 13 may include indium tin oxide, the indium oxide in the indium tin oxide is able to get electrons more readily than silver ions, the indium oxide undergoes a reduction reaction to get the elemental In, but the elemental In does not aggregate to form metal particles. The indium tin oxide or indium zinc oxide can effectively protect the isolation pillars 12, prevent the electrons in the first metal material 122 from being acquired by the silver ions, thereby avoiding the formation of Ag metal particles, and avoiding the subsequent water oxygen intrusion.

FIG. 13 is a cross-sectional view of another partition area according to an embodiment of the present application; optionally, the conductive structure 13 includes a first material sub-layer 131, a second material sub-layer 142, and a third material sub-layer 133 away from the substrate 11 in sequence. The first material sub-layer 131 and the third material sub-layer 133 include indium-tin oxide or indium-zinc oxide, and the second material sub-layer 132 includes silver. In the present embodiment, the conductive structure 13 includes multiple layers of materials, and the conductive structure 13 may include a first material sub-layer 131, a second material sub-layer 132, and third material sub-layer 133 away from the substrate 11 in sequence, among which the first material sub-layer 131 and the third material sub-layer 133 each are provided with a first conductive material. In the present embodiment, the first conductive material may be indium-tin oxide or indium-zinc oxide; the electron-accepting ability of the conductive material is greater than that of silver ions, so the first conductive material is more likely to get electrons from the first metal material in the first metal layer than silver ions, effectively preventing the deposition of the particles of metal silver on the isolation pillar 12.

Continuing to refer to FIG. 13, optionally, the display panel may further include an conductive portion 15, the conductive portion 15 is disposed in the same layer as the conductive structure 13, a plurality of isolation pillars 12 may be disposed sequentially in a direction from the aperture area A1 to the partition area A2, and the conductive portion 15 is disposed between two adjacent isolation pillars 12. In the present embodiment, when the conductive structure 13 is disposed in the partition area A2, the conductive portion 15 may also be disposed in the partition area A2, and the material of the conductive portion 15 is of the same material as the conductive structure 13. Because a plurality of isolation pillars 12 are sequentially provided in the direction from the aperture area A1 toward the partition area A2, the conductive portion 15 is disposed between the isolation pillars 12. The arrangement of the conductive portion 15 can further consume the electrons lost by the first metal material in the acidic etching solution, reduce the risk of silver ions being reduced, further enhance the smoothness of the surface of the isolation pillars 12, enhance the process yield of the subsequent film layer, and further enhance the quality of the display panel. Optionally, the conductive portion 15 and the conductive structure 13 may be disposed in the same layer to further save the production process. Optionally, in the same manner as the conductive structure 13, the conductive section 15 may be provided with a first material layer 151, a second material layer 152, and a third material layer 153 in the direction away from the substrate 11. The first material layer 151 is provided in the same layer as the first material sub-layer 131, the second material layer 152 is provided in the same layer as the second material sub-layer 132, and the third material layer 153 is provided in the same layer as the third material sub-layer 133. Exemplarily, when the conductive structure 13 is a stacked structure of ITO/Ag/ITO, the first material sub-layer 131 and the first material layer 151 are ITO, the second material layer 152 and the second material sub-layer 132 are Ag, and the third material layer 153 and the third material sub-layer 133 are ITO.

Continuing to refer to FIG. 13, optionally, the first metal layer 121 may include a first metal sub-layer 121a, a second metal sub-layer 121b, and a third metal sub-layer 121c disposed sequentially away from the substrate 11. The outer edge of the first metal sub-layer 121a and the outer edge of the third metal sub-layer 121c extend out of the outer edge of the second metal sub-layer 121b to form a concave in the sidewall of the isolation pillar 12. In the present embodiment, the first metal layer 121 may include a plurality of metal layers provided in an overlapping manner. A first metal sub-layer 121a, a second metal sub-layer 121b, and a third metal sub-layer 121c are provided sequentially in a direction away from the substrate 11. The outer edges of both the first metal sub-layer 121a and the third metal sub-layer 121c extend longer than the outer edges of the second metal sub-layer 121b, and relative to the first metal sub-layer 121a and the third metal sub-layer 121c, the second metal sub-layer 121b is concave, so that the cross-section of the isolation pillar 12 forms an “H” shape, and it is difficult for the metal layer on the isolation pillar 12 to cover the sidewalls of the isolation pillar 12. The specific preparation process is as follows: after sequentially preparing the stacked structure of the isolation pillar 12 and the patterned structure of the anode 171, a process is required to side-etch the stacked structure of the isolation pillars 12 to form the “H” shape shown in FIG. 13. Optionally, the second metal sub-layer 121b may also include the first metal material. After the conductive structure 13 is formed, the acidic etching solution in the side-etching process of the isolation pillar 12 will be in direct contact the second metal sub-layer 121b, and there is a risk that the silver ions get electrons to form metal particles, but in the present embodiment, the conductive structure 13 is in contact with the first metal layer 121 to get electrons faster than the silver ions, preventing the buildup of the metal particles of the silver on the isolation pillars 12, and preventing the aforementioned metal particles from forming cracks on the encapsulation layer, thereby avoiding the water oxygen intrusion into the display panel and improving the process yield of the display panel. Optionally, the materials of the first metal sub-layer 121a and the third metal sub-layer 121c may include titanium, and the material of the second metal sub-layer 121b may include aluminum. The electron-accepting ability of the aluminum is less than the electron-accepting ability of the silver ions and less than the electron-accepting ability of the first conductive material.

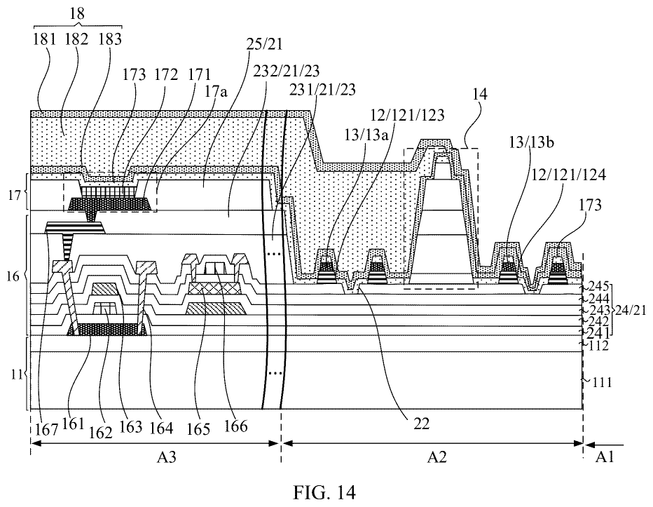

FIG. 14 is a cross-sectional view of another display panel along a line b-b′ shown in FIG. 2. Optionally, the display panel may further include a plurality of insulating layers 21 disposed on a first side of the substrate 11, and also a plurality of recesses 22. The corresponding recess 22 is disposed between two isolation pillars 12 adjacent in a direction from the aperture area A1 to the display area A3, and the recesses 22 expose at least part of the insulating layers 21. In the present embodiment, at least one layer of the insulating layer 21 is removed when the isolation pillars 12 are disposed in the partition area A2, as shown in FIG. 14, and the removal of the insulating layer 21 is not performed on the dam portion 14. Exemplarily, the flattened layer 23 and the pixel-defining layer 25 may be removed in the partition area A2, as shown in FIG. 14, on the basis of the removal of part of the insulating layer 21 in the partition area A2, a plurality of recesses 22 may be provided in the present embodiment, and the setting of the recesses 22 may further isolate the electrical connection of the cathode 173 in the partition area A2 to avoid the damage to the display area A3 caused by the water oxygen intrusion in the partition area A2, and enhance display panel the reliability of the display panel.

Continuing to refer to FIG. 14, optionally, the insulating layer 21 includes an interlayer insulating layer 24, a flattened layer 23, and a pixel-defining layer 25 away from the substrate in sequence. The recesses 22 penetrate at least part of the thickness of the interlayer insulating layer 24. In the present embodiment, the driving circuit layer 16 specifically includes a first active layer 161, a first gate layer 162, a first electrode plate layer 163, a second active layer 165, a second gate layer 166, a source-drain metal layer 164, and an auxiliary connecting layer 167. The interlayer insulating layer 24 may include a first gate insulating layer 241 between the first active layer 161 and the first gate layer 162, a capacitive dielectric layer 242 between the first gate layer 162 and the first electrode plate layer 163, a first dielectric layer 243 between the first electrode plate layer 163 and the second active layer 165, a second gate insulating layer 244 between the second active layer 165 and the second gate layer 166, and a second dielectric layer 245 between the second gate layer 166 and the source-drain metal layer 164. In addition, the flattened layer 23 may also include a first flattened layer 231 and a second flattened layer 232, the first flattened layer 231 is disposed between the source-drain metal layer 164 and the auxiliary connecting layer 167, and the second flattened layer 232 is disposed between the auxiliary connecting layer 167 and the anode 171. As shown in FIG. 14, the pixel-defining layer 25 and the flattened layer 23 may be removed from the partition area A2, and then the recesses 22 may penetrate the second dielectric layer 245, the second gate insulation layer 244, the first dielectric layer 243, the capacitive dielectric layer 242, and at least part of the thickness of the first gate insulation layer 241. FIG. 14 illustrates an example of the recess 22 penetrating the second dielectric layer 245 and exposing the second gate insulating layer 244. Of course, it is possible to only remove the pixel-defining layer 25 and the second flattened layer 232 from the partition area A2, and the recess 22 penetrates the first flattened layer 231 and at least part of the interlayer insulating layer 24, such as the second dielectric layer 245. In the present embodiment, there is no special limit on the number of insulating layers to be removed from the partition area A2. The arrangement of the recess 22 effectively isolates the connection between the recess 22 and the cathode 173 on the isolation pillar 12, avoids the impact on the signals of the pixel driving circuit array area through the cathode 173 during the water oxygen intrusion in the partition area A2, and avoids the interference with the signals of the pixel driving circuits generated by the static electricity in the partition area A2, and effectively improves the display effect of the display panel.

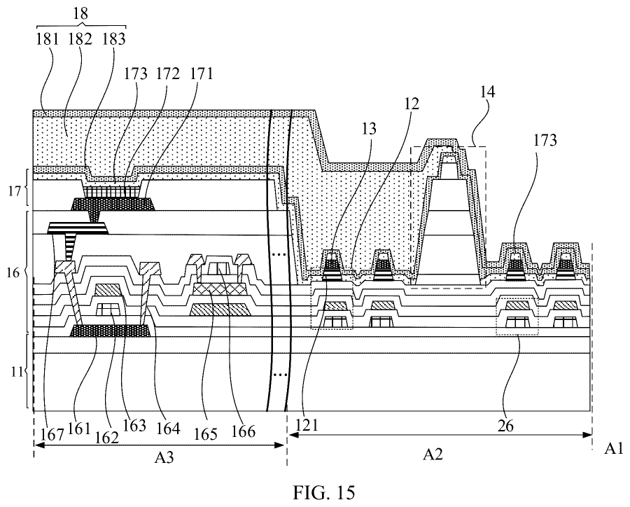

FIG. 15 is a cross-sectional view of another display panel along a line b-b′ shown in FIG. 2. Optionally, the isolation pillar 12 may further include a padding structure 26, which is disposed between the substrate 11 and the first metal layer 121. In the present embodiment, the isolation pillar 12 includes not only the first metal layer 121, but may also include other metal or non-metal stacked structures, which may be referred to as the padding structure 26. The padding structure 26 is disposed between the substrate 11 and the first metal layer 121 for controlling the overall height of the isolation pillar 12 to allow for concaves between adjacent isolation pillars 12 to interrupt the connection of the cathodes 173. Optionally, in a plane parallel to the substrate 11, the area of the padding structure 26 may be smaller than the area of the first metal layer 121, so as to enable a relatively large concave to be formed between two adjacent isolation pillars 12, which further ensures that the cathode 173 in the region between the isolation pillars 12 is disconnected from the cathodes 173 on the isolation pillars 12, and enhances the quality of the display panel. Continuing to refer to FIG. 15, optionally, the padding structure 26 may include at least the first gate layer 162 and the first electrode plate layer 163. In addition, the padding structure 26 may include other metal and non-metal layers between the source-drain metal layer 164 and the substrate 11, which are not specifically limited in the present embodiment.

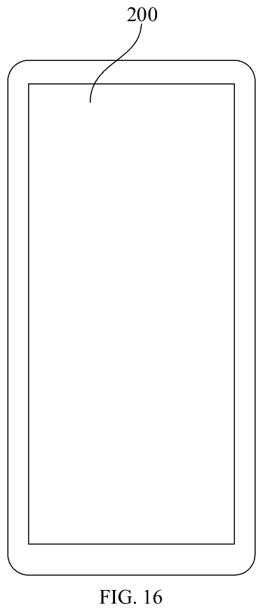

Embodiments of the present application also provide an electronic device. FIG. 16 is a schematic view of an electronic device according to an embodiment of the present application, and as shown in FIG. 16, the electronic device provided in the present embodiments of the present application includes an organic light-emitting display panel 200 as described in any one of the embodiments of the present application. The electronic device may be a cellular phone, as shown in FIG. 16, or it may also be a computer, a television, a smart wearable device, and the like, and the present embodiments do not make any special limitation thereon.

A display device provided in the embodiments of the present application includes the technical features of the display panel provided in any of the embodiments of the present application, with the beneficial effects possessed by the corresponding features, which will not be repeated herein.

What is claimed is:

1. A display panel comprising:
an aperture area;
a partition area surrounding the aperture area;
a display area surrounding the partition area;
a substrate;
at least one isolation pillar disposed on a first side of the substrate and disposed in the partition area around the aperture area, the isolation pillar comprising a first metal layer, the first metal layer comprising a first metal material; and
a conductive structure disposed on a side of the first metal layer away from the substrate, the conductive structure overlapping with the first metal layer in a direction perpendicular to the substrate and comprising a first conductive material,
wherein electron-accepting ability of the first conductive material is greater than that of silver ions and also that of the first metal material.

2. The display panel according to claim 1, wherein the conductive structure is electrically connected to the first metal layer.

3. The display panel according to claim 1, wherein the partition area comprises a dam portion, a plurality of the isolation pillars being provided between the dam portion and the display area as inner isolation pillars, and
wherein the conductive structure comprises a first conductive structure disposed on at least one of the plurality of inner isolation pillars.

4. The display panel according to claim 3, comprising the first conductive structures in a number of more than two, which are disposed on different ones of the inner isolation pillars, and widths of which on the inner isolation pillars are same.

5. The display panel according to claim 3, comprising the first conductive structures in a number of more than two, which are disposed on different ones of the inner isolation pillars, and widths of which on the inner isolation pillars are different and gradually decrease in a direction from the display area to the aperture area.

6. The display panel according to claim 3, wherein a plurality of the isolation pillars are provided between the dam portion and the aperture area as outer isolation pillars, and the conductive structure comprises a plurality of second conductive structures disposed on a side of at least one of the outer isolation pillars away from the substrate.

7. The display panel according to claim 6, wherein the second conductive structures are spaced apart.

8. The display panel according to claim 6, wherein a width of the first conductive structure is same as a width of the second conductive structure.

9. The display panel according to claim 1, wherein viewed in a direction perpendicular to the substrate, the conductive structure forms a ring on the same isolation pillar.

10. The display panel according to claim 9, wherein in a direction perpendicular to the substrate, the conductive structure comprises a plurality of sub-conductive structures disposed non-continuously in sequence on the same isolation pillar.

11. The display panel according to claim 9, wherein 3 um≤h1≤h2, or 3 um≤h2<h1, h1 being a width of the conductive structure in a direction from the aperture area to the display area, and h2 being a width of the first metal layer in a direction from the aperture area to the display area.

12. The display panel according to claim 1, wherein a material of the conductive structure comprises indium tin oxide or indium zinc oxide.

13. The display panel according to claim 12, wherein the conductive structure comprises a first material sub-layer, a second material sub-layer and a third material sub-layer disposed sequentially away from the substrate, the first material sub-layer and the third material sub-layer comprising indium tin oxide or indium zinc oxide, and the second material sub-layer comprising silver.

14. The display panel according to claim 12, further comprising a driving circuit layer and a light-emitting device layer, the light-emitting device layer comprising an anode, an organic material layer and a cathode, and a material of the conductive structure being same as that of the anode.

15. The display panel according to claim 1, further comprising an conductive portion disposed in a same layer as the conductive structure,
wherein a plurality of the isolation pillars are disposed sequentially in a direction from the aperture area to the partition area, and the conductive portion is disposed between two adjacent ones of the isolation pillars.

16. The display panel according to claim 1, wherein the first metal layer comprises a first metal sub-layer, a second metal sub-layer, and a third metal sub-layer disposed sequentially away from the substrate, an outer edge of the first metal sub-layer and an outer edge of the third metal sub-layer extending out of an outer edge of the second metal sub-layer to form a concave in a sidewall of the isolation pillar.

17. The display panel according to claim 16, wherein the second metal sub-layer includes the first metal material.

18. The display panel according to claim 6, further comprising:
a plurality of insulating layers disposed on the first side of the substrate;
a plurality of recesses, each of the plurality of recesses being disposed between two of the isolation pillars adjacent in a direction from the aperture area to the display area, and exposing at least part of the plurality of insulating layers.

19. The display panel according to claim 1, wherein the isolation pillar further includes a padding structure disposed between the substrate and the first metal layer.

20. A display device comprising a display panel which comprises:
an aperture area;
a partition area surrounding the aperture area;
a display area surrounding the partition area;
a substrate;
at least one isolation pillar disposed on a first side of the substrate and disposed in the partition area around the aperture area, the isolation pillar comprising a first metal layer, the first metal layer comprising a first metal material; and
a conductive structure disposed on a side of the first metal layer away from the substrate, the conductive structure overlapping with the first metal layer in a direction perpendicular to the substrate and comprising a first conductive material,
wherein electron-accepting ability of the first conductive material is greater than that of silver ions and also that of the first metal material.
